(19) United States
(12) Patent Application Publication
(10) Pub. No.: US 2026/0032846 A1
(43) Pub. Date: Jan. 29, 2026

(54) POWER CONVERSION DEVICE

(71) Applicant: Mitsubishi Electric Corporation, Chiyoda-ku, Tokyo (JP)

(72) Inventors: Atsushi HOSOKAWA, Chiyoda-ku, Tokyo (JP); Shohei HIGASHITANI, Chiyoda-ku, Tokyo (JP); Shota SATO, Chiyoda-ku, Tokyo (JP); Ryo TAKEI, Chiyoda-ku, Tokyo (JP)

(73) Assignee: Mitsubishi Electric Corporation, Chiyoda-ku, Tokyo (JP)

(21) Appl. No.: 18/992,235

(22) PCT Filed: Jul. 4, 2023
(86) PCT No.: PCT/JP2023/024793

§ 371 Date: Jan. 8, 2025

(30) Foreign Application Priority Data
Sep. 2, 2022 (JP) 2022-140139

(51) Int. Cl. H05K 7/14; H05K 7/20

(52) U.S. Cl. CPC H05K 7/1432; H05K 7/2089

(57) ABSTRACT

Provided is a power conversion device in which replacement of a capacitor is easy and a connection failure is unlikely to occur between the capacitor and an electronic component. The power conversion device includes: a printed circuit board having a first surface; at least one capacitor mounted on the first surface of the printed circuit board; and an input-side semiconductor module and an output-side semiconductor module disposed to sandwich the at least one capacitor in a first direction along the first surface and electrically connected to each other via the at least one capacitor. The printed circuit board is detachably supported by each of the input-side semiconductor module and the output-side semiconductor module.

### TECHNICAL FIELD

The present disclosure relates to a power conversion device.

### BACKGROUND ART

In a conventional power conversion device, a capacitor is electrically connected between an input-side semiconductor element and an output-side semiconductor element and is mounted on a substrate that is different from a substrate on which the input-side semiconductor element and the output-side semiconductor element are mounted, and the substrate on which the capacitor is mounted is detachable from the substrate on which the semiconductor elements are mounted. In such a power conversion device, the replacement of the capacitor can be easily performed by attaching the substrate on which the capacitor is mounted to or detaching the substrate on which the capacitor is mounted from the substrate on which the semiconductor elements are mounted, as compared with a power conversion device in which the capacitor is mounted on the same substrate with the semiconductor elements.

In a power supply system described in Japanese Patent No. 6190183 (PTL 1), a substrate on which a plurality of capacitors are mounted is detachably connected to a power supply substrate on which a power supply is mounted via a connector.

### CITATION LIST

### Patent Literature

### PTL 1: Japanese Patent No. 6190183

### SUMMARY OF INVENTION

### Technical Problem

In the power supply system described in PTL 1, the capacitor substrate is supported on the power supply substrate via a connector in a cantilever state. The capacitor substrate includes a portion connected to the power supply substrate via the connector and a portion protruding outward from the former portion, and the capacitor is mounted on the latter portion. Thus, a stress is applied to the connection portion between the connector and the capacitor board, which may cause a connection failure to occur between the capacitor and the electronic components such as the power supply mounted on the power supply board.

A main object of the present disclosure is to provide a power conversion device in which replacement of a capacitor is easy and a connection failure is unlikely to occur between the capacitor and an electronic component.

### Solution to Problem

The power conversion device according to an embodiment of the present disclosure includes a printed circuit board having a first surface, at least one capacitor mounted on the first surface of the printed circuit board, and an input-side semiconductor module and an output-side semiconductor module disposed to sandwich the at least one capacitor in a first direction along the first surface and electrically connected to each other via the at least one capacitor. The printed circuit board is detachably supported by each of the input-side semiconductor module and the output-side semiconductor module.

### Advantageous Effects of Invention

According to the present disclosure, it is possible to provide a power conversion device in which replacement of a capacitor is easy and a connection failure is unlikely to occur between the capacitor and an electronic component.

### BRIEF DESCRIPTION OF DRAWINGS

FIG. 1 is a circuit diagram illustrating a power conversion device according to a first embodiment.

FIG. 2 is a perspective view illustrating the power conversion device according to the first embodiment.

FIG. 3 is a side view illustrating the power conversion device according to the first embodiment.

FIG. 4 is a perspective view illustrating capacitors arranged on a printed circuit board of the power conversion device according to the first embodiment.

FIG. 5 is a circuit diagram illustrating a modification of the power conversion device according to the first embodiment.

FIG. 6 is a side view illustrating another modification of the power conversion device according to the first embodiment.

FIG. 7 is a cross-sectional view illustrating a first conductor pattern on a printed circuit board of a power conversion device according to a second embodiment.

FIG. 8 is a cross-sectional view illustrating a second conductor pattern on the printed circuit board of the power conversion device according to the second embodiment.

FIG. 9 is a side view illustrating a power conversion device according to a third embodiment.

FIG. 10 is a side view illustrating a power conversion device according to a fourth embodiment.

FIG. 11 is a side view illustrating a power conversion device according to a fifth embodiment.

FIG. 12 is a perspective view illustrating capacitors arranged on a printed circuit board of a power conversion device according to a fifth embodiment.

### DESCRIPTION OF EMBODIMENTS

Hereinafter, embodiments will be described with reference to the drawings. In the following description, the same or corresponding portions are denoted by the same reference numerals, and the description thereof will not be repeated.

### First Embodiment

### <Configuration of Power Conversion Device>

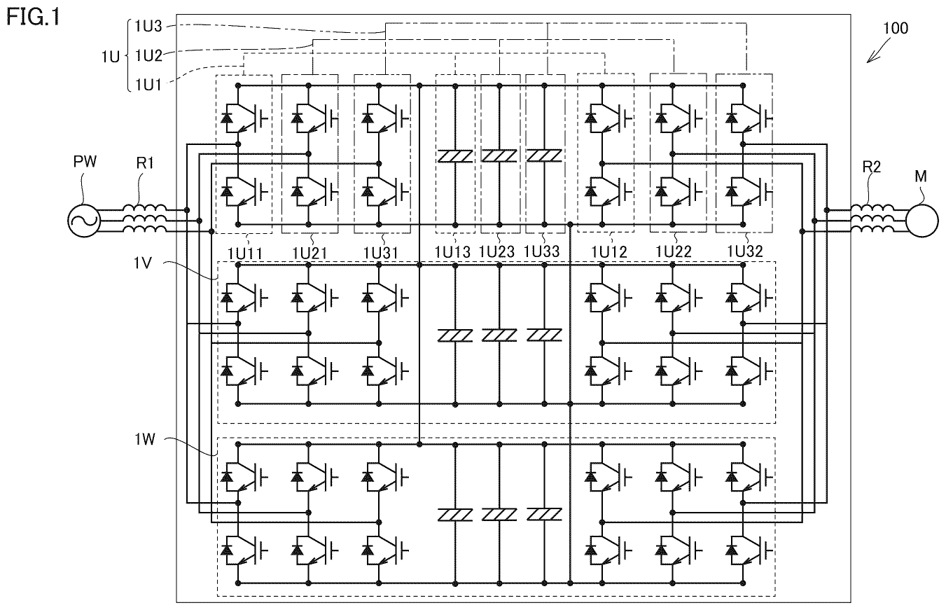

As illustrated in FIG. 1, a power conversion device 100 according to a first embodiment is a three-phase power conversion device.

As illustrated in FIG. 1, the power conversion device 100 includes a first-phase unit group 1U, a second-phase unit group 1V, and a third-phase unit group 1W. The first-phase unit group 1U, the second-phase unit group 1V, and the third-phase unit group 1W are configured to input and output a U phase power, a V phase power, and a W phase power, respectively. Each of the first-phase unit group 1U, the second-phase unit group 1V, and the third-phase unit group 1W includes a plurality of power conversion circuit units. Each of the plurality of power conversion circuit units includes a plurality of electronic components constituting a power conversion circuit. Preferably, the first-phase unit group 1U, the second-phase unit group 1V, and the third-phase unit group 1W have the same configuration. In the present embodiment. the first-phase unit group 1U will be described as a representative of the first-phase unit group 1U, the second-phase unit group 1V, and the third-phase unit group 1W.

As illustrated in FIG. 1, the first-phase unit group 1U includes a first-phase first power conversion circuit unit 1U1, a first-phase second power conversion circuit unit 1U2, and a first-phase third power conversion circuit unit 1U3. In FIG. 1, the constituent elements of the first-phase first power conversion circuit unit 1U1 are enclosed by a dash line. The constituent elements of the first-phase second power conversion circuit unit 1U2 are enclosed by a dash-dot line. The constituent elements of the first-phase third power conversion circuit unit 1U3 are enclosed by a two-dot chain line. Each of the first-phase first power conversion circuit unit 1U1, the first-phase second power conversion circuit unit 1U2, and the first-phase third power conversion circuit unit 1U3 constitutes a one-phase one-parallel power conversion circuit unit. The first-phase first power conversion circuit unit 1U1, the first-phase second power conversion circuit unit 1U2, and the first-phase third power conversion circuit unit 1U3 are connected in parallel to each other.

In each of the first-phase unit group 1U, the second-phase unit group 1V and the third-phase unit group 1W, the number of parallel power conversion circuit units may be appropriately determined according to the specification of the power conversion device 100. The number of parallel power conversion circuit units for each phase may be, for example, two. For example, the first-phase unit group 1U may be constituted by a first-phase first power conversion circuit unit 1U1 and a first-phase second power conversion circuit unit 1U2 connected in parallel to each other.

Preferably, the first-phase first power conversion circuit unit 1U1, the first-phase second power conversion circuit unit 1U2, and the first-phase third power conversion circuit unit 1U3 have the same configuration. Preferably, the power conversion circuit unit of the first-phase unit group 1U, the power conversion circuit unit of the second-phase unit group 1V, and the power conversion circuit unit of the third-phase unit group 1W have the same configuration. In the present embodiment, the first-phase first power conversion circuit unit 1U1 will be described as a representative of the power conversion circuit unit of the first-phase unit group 1U, the power conversion circuit unit of the second-phase unit group 1V, and the power conversion circuit unit of the third-phase unit group 1W.

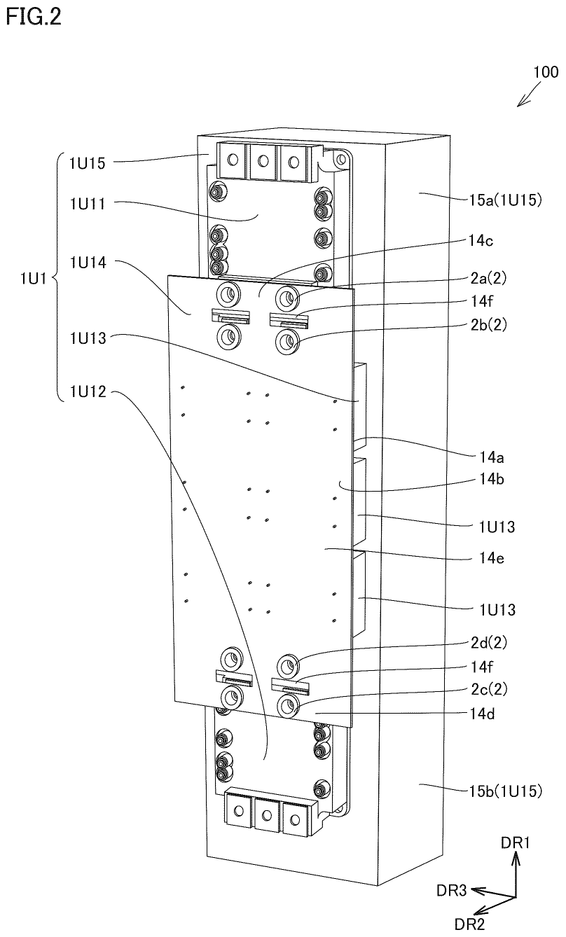

As illustrated in FIG. 2, the first-phase first power conversion circuit unit 101 includes, for example, a first input-side semiconductor module 1U11, a first output-side semiconductor module 1U12, a plurality of first-phase first capacitors 1U13, a printed circuit board 1U14, and a cooler 1U15.

The first input-side semiconductor module 1U11 and the first output-side semiconductor module 1U12 are electrically connected to each other via the plurality of first-phase first capacitors 1U13. The first input-side semiconductor module 1U11 and the first output-side semiconductor module 1U12 are spaced apart from each other in a first direction DR1. The first input-side semiconductor module 1U11 and the first output-side semiconductor module 1U12 are disposed to sandwich the plurality of first-phase first capacitors 1U13 in the first direction DR1.

The first-phase first power conversion circuit unit 1U1 may include at least one first-phase first capacitor 1U13. In this case, the first input-side semiconductor module 1U11 and the first output-side semiconductor module 1U12 may be disposed to sandwich the at least one first-phase first capacitor 1U13 in the first direction DRI. In the case where the first-phase first power conversion circuit unit 1U1 includes a plurality of first-phase first capacitors 1U13, the first input-side semiconductor module 1U11 and the first output-side semiconductor module 1U12 may be disposed to sandwich at least one of the plurality of first-phase first capacitors 1U13 in the first direction DR1.

Each of the first input-side semiconductor module 1U11 and the first output-side semiconductor module 1U12 is detachably supported by, for example, the cooler 1U15. Each of the first input-side semiconductor module 1U11 and the first output-side semiconductor module 1U12 is fixed to the cooler 1U15 by, for example, screws. The cooler 1U15 includes a first cooling unit 15a connected to the first input-side semiconductor module 1U11 and a second cooling unit 15b connected to the first output-side semiconductor module 1U12. Preferably, the first cooling unit 15a and the second cooling unit 15b are connected to the first input-side semiconductor module 1U11 and the first output-side semiconductor module 1U12, respectively, via heat dissipation grease or a heat dissipation sheet, for example.

The first input-side semiconductor module 1U11 and the first output-side semiconductor module 1012 are configured in such a manner that when one functions as a converter, the other one functions as an inverter. The first input-side semiconductor module 1U11 and the first output-side semiconductor module 1U12 are constituted by, for example, a 2-in-1 package in which two insulated gate bipolar transistors (IGBT) are built into one package. The first input-side semiconductor module 1U11 and the first output-side semiconductor module 1U12 are not limited to a 2-in-1 package, and may be a 1-in-1 package or the like. In this case, the packages are connected to each other by, for example, a bus bar. The first input-side semiconductor module 1U11 and the first output-side semiconductor module 1U12 may be constituted by a metal oxide semiconductor field effect transistor (MOSFET) or a transistor. The first input-side semiconductor module 1U11 and the first output-side semiconductor module 1U12 may be prepared as a general-purpose semiconductor module.

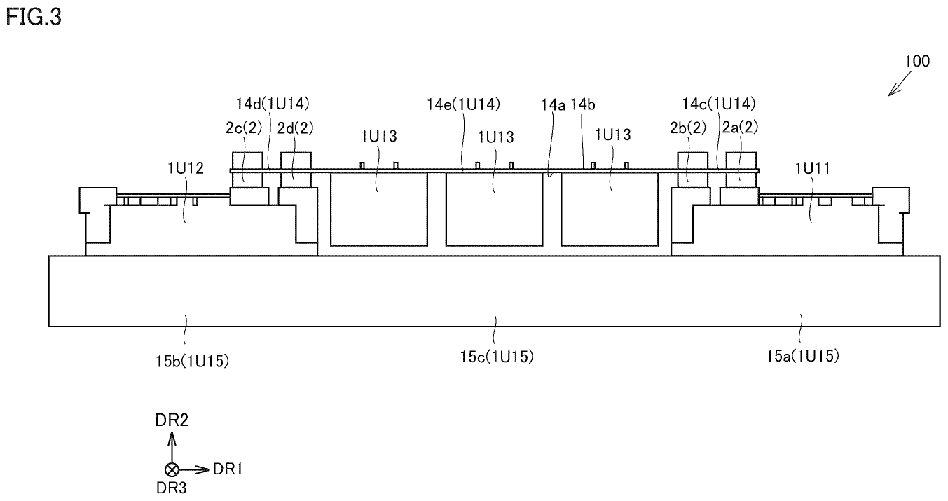

As illustrated in FIG. 3, each of the plurality of first-phase first capacitors 1U13 is spaced apart from the first input-side semiconductor module 1U11, the first output-side semiconductor module 1U12, and the cooler 1U15. Preferably, each first-phase first capacitor 1U13 is not in contact with the other components. As a result. each of the first-phase first capacitors 1U13 is less likely to be affected by vibration and heat from the other components. Each of the first-phase first capacitors 1U13 may be connected to an adjacent component such as the first-phase first capacitor 1U13, the printed circuit board 1U14, or the cooler 15 via an elastic spacer. The first-phase first capacitor 1U13 may be connected to the cooler 1U15 via a thermal conductive spacer.

When the first-phase first capacitor 1U13 is connected to the cooler 1015, the first-phase first capacitor 1U13 may be cooled by the cooler 1U15 by setting the temperature of the cooler 1U15 equal to or lower than the temperature of the first-phase first capacitor 1U13.

Each of the plurality of first-phase first capacitors 1U13 may be configured to function as a smoothing capacitor. For example, the first-phase first capacitor 1U13 is a film capacitor, an electrolytic capacitor, or the like. The type of the first-phase first capacitor 1U13 may be appropriately determined according to its usage. A plurality of capacitors may be connected in series or in parallel to each other and mounted on the printed circuit board 1U14. For example, the first-phase first capacitor 1U13 is mounted on the printed circuit board 1U14 by soldering. The first-phase first capacitor 1U13 may be mounted on the printed circuit board 1U14 by another mounting method such as caulking.

Each of the plurality of first-phase first capacitors 1U13 may be a lead capacitor. In other words, each of the plurality of first-phase first capacitors 1U13 may include a plurality of leads, each lead passes through each of the plurality of through holes formed in the printed circuit board 1U14 and may be fixed by soldering. Alternatively, each of the plurality of first-phase first capacitors 1U13 may be a surface mount capacitor. In other words, each of the plurality of first-phase first capacitors 1U13 may have a mounting surface that faces a first surface 14a of the printed circuit board 1U14, and the first surface 14a of the printed circuit board 1014 and the mounting surface of the first-phase first capacitor 1U13 may be fixed by soldering.

As illustrated in FIG. 3, the printed circuit board 1U14 has a first surface 14a and a second surface 14b opposite to the first surface 14a. The first surface 14a faces the cooler 1U15. The first surface 14a faces a part of the first input-side semiconductor module 1U11, a part of the first output-side semiconductor module 1U12, and a part of the cooler 1U15. Each of the first surface 14a and the second surface 14b is parallel to the first direction DR1. In the present specification, a direction orthogonal to the first surface 14a is defined as a second direction DR2, and a direction orthogonal to both the first direction DR1 and the second direction DR2 is defined as a third direction DR3. The first input-side semiconductor module 1U11 and the first output-side semiconductor module 1U12 are disposed on the side of the first surface 14a of the printed circuit board 1U14. The plurality of first-phase first capacitors 1U13 are mounted on the first surface 14a of the printed circuit board 1014. No electronic component such as a capacitor is mounted on the second surface 14b of the printed circuit board 1U14.

The printed circuit board 1U14 is detachably supported by each of the first input-side semiconductor module 1U11 and the first output-side semiconductor module 1U12. In other words, the printed circuit board 1U14 is supported by both the first input-side semiconductor module 1U11 and the first output-side semiconductor module 1U12.

As illustrated in FIG. 3, the printed circuit board 1U14 includes a first portion 14c, a second portion 14d, and a third portion 14e. The first portion 14c is detachably connected to the first input-side semiconductor module 1U11. The first portion 14c faces the first input-side semiconductor module 1U11 in the second direction DR2. The first portion 14c is electrically connected to the first input-side semiconductor module 1U11. The second portion 14d is detachably connected to the first output-side semiconductor module 1012. The second portion 14d faces the first output-side semiconductor module 1U12 in the second direction DR2, and is electrically connected to the first output-side semiconductor module 1U12. The third portion 14e is located between the first portion 14c and the second portion 14d in the first direction DR1. The lower surface of the first portion 14c, the lower surface of the second portion 14d, and the lower surface of the third portion 14e constitute the first surface 14a. The upper surface of the first portion 14c, the upper surface of the second portion 14d, and the upper surface of the third portion 14e constitute the second surface 14b. The plurality of first-phase first capacitors 1U13 are mounted on the first surface 14a of the third portion 14e of the printed circuit board 1U14. Each of the first portion 14c and the second portion 14d is, for example, an end portion of the printed circuit board 1U14 in the first direction DR1.

The first portion 14c is electrically connected to the first input-side semiconductor module 1U11 via a first terminal 2a and a second terminal 2b. The first terminal 2a and the second terminal 2b have different potentials. One of the first terminal 2a and the second terminal 2b is a positive potential terminal, and the other one of the first terminal 2a and the second terminal 2b is a negative potential terminal.

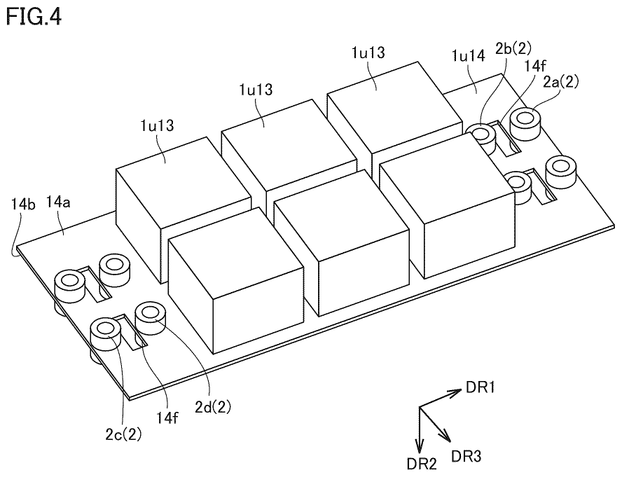

The first terminal 2a and the second terminal 2b are detachably fixed to at least one of the first portion 14e of the printed circuit board 1U14 and the first input-side semiconductor module 1U11. For example, the first terminal 2a and the second terminal 2b are non-detachably fixed to the first portion 14c, and are detachably fixed to the first input-side semiconductor module 1U11. The printed circuit board 1014 is not directly fixed to the first semiconductor module 1U11, but is fixed to the first semiconductor module 1U11 via the first terminal 2a and the second terminal 2b. Thus, it is possible to ensure an insulation distance between the first terminal 2a and the second terminal 2b, and it is possible to reduce or stabilize the contact resistance with each terminal of the first semiconductor module 1U11. The method of fixing the first terminal 2a and the second terminal 2b to the printed circuit board 1U14 or the first input-side semiconductor module 1U11 is not particularly limited. For example, the first portion 14c is formed with a via hole through which each of the first terminal 2a and the second terminal 2b is passed and fixed by caulking, soldering, or the like. The first input-side semiconductor module 1U11 is formed with a terminal that is in contact with each of the first terminal 2a and the second terminal 2b and is electrically connected thereto, and a female screw for screwing a bolt. In the configuration illustrated in FIG. 4, the printed circuit board 1U14, the first terminal 2a, the second terminal 2b, and the first input-side semiconductor module 1U11 may be fixed to each other by aligning the female screws of the first input-side semiconductor module 1U11 with the hole of the first terminal 2a and the hole of the second terminal 2b and tightening the bolts. The bolts can be easily attached or detached so as to install or replace the printed circuit board 1U14. In addition, since the bolts can be attached or detached only on one surface of the power conversion device 100 (for example, when the power conversion device 100 is applied to a control panel to be described hereinafter, a surface thereof facing the front surface of the control panel) in the second direction DR2, it is easy to perform the maintenance operation or the like. The first terminal 2a and the second terminal 2b may be detachably fixed to both the first portion 14c and the first input-side semiconductor module 1U11.

As illustrated in FIG. 4, the first terminal 2a and the second terminal 2b are spaced apart from each other. The first terminal 2a and the second terminal 2b are spaced apart from each other in the first direction DR1, for example. Preferably, the first portion 14c is formed with a slit 14f between the first terminal 2a and the second terminal 2b. The slit 14f is formed to cross an imaginary straight line that connects the first terminal 2a and the second terminal 2b at the shortest distance, Due to the formation of the slit 14f, the creepage distance between the first terminal 2a and the second terminal 2b becomes longer than the shortest distance (the length of the imaginary straight line) between the first terminal 2a and the second terminal 2b. When viewed from the second direction DR2, the slit 14f has, for example, a longitudinal direction and a lateral direction. The longitudinal direction of the slit 14f is orthogonal to the virtual straight line, for example.

The second portion 14d is electrically connected to the first output-side semiconductor module 1U12 via a third terminal 2c and a fourth terminal 2d. The third terminal 2c and the fourth terminal 2d may have the same configuration as the first terminal 2a and the second terminal 2b. The third terminal 2c and the fourth terminal 2d have different potentials. One of the third terminal 2c and the fourth terminal 2d is a positive potential terminal, and the other one of the third terminal 2c and the fourth terminal 2d is a negative potential terminal.

The third terminal 2c and the fourth terminal 2d are detachably fixed to at least one of the second portion 14d of the printed circuit board 1U14 and the first output-side semiconductor module 1U12. For example, the third terminal 2c and the fourth terminal 2d are non-detachably fixed to the second portion 14d, and are detachably fixed to the first output-side semiconductor module 1012. The method of fixing the third terminal 2c and the fourth terminal 2d to the printed circuit board 1014 or the first output-side semiconductor module 1U12 is not particularly limited.

As illustrated in FIG. 4, the third terminal 2c and the fourth terminal 2d are spaced apart from each other. The third terminal 2c and the fourth terminal 2d are spaced apart from each other in the first direction DR1, for example. Preferably, the second portion 14d is formed with a slit 14f between the third terminal 2e and the fourth terminal 2d. The slit 14f is formed to cross an imaginary straight line that connects the third terminal 2c and the fourth terminal 2d at the shortest distance. Due to the formation of the slit 14f, the creepage distance between the third terminal 2c and the fourth terminal 2d becomes longer than the shortest distance (the length of the imaginary straight line) between the third terminal 2e and the fourth terminal 2d. When viewed from the second direction DR2, the slit 14f has, for example, a longitudinal direction and a lateral direction. The longitudinal direction of the slit 14f is orthogonal to the virtual straight line, for example.

The material of the first terminal 2a, the second terminal 2b, the third terminal 2c, or the fourth terminal 2d may be any electrically conductive material, and may include, for example, copper (Cu) or aluminum (Al). As illustrated in FIG. 4, each terminal is, for example, a cylinder, but is not limited thereto, and it may be a polygonal prism such as a quadrangular prism.

For example, only the first-phase first capacitor 1U13 is mounted on the first surface 14a of the printed circuit board 1U14. The other electronic components may be mounted on the first surface 14a in addition to the first-phase first capacitor 1U13. For example, at least one of a resistor and a capacitor to be used in a snubber circuit for preventing a surge voltage from being generated when the semiconductor module performs a switching operation may be further mounted on the first surface 14a.

The printed circuit board 1U14 is, for example, a multilayer substrate that includes a plurality of conductor patterns stacked in the second direction DR2. The shape of each of the plurality of conductor patterns included in the printed circuit board 1U14 is not particularly limited.

As described above, the cooler 1U15 includes a first cooling unit 15a and a second cooling unit 15b. The cooler 1U15 illustrated in FIG. 3 further includes a third cooling unit 15c connected between the first cooling unit 15a and the second cooling unit 15b in the first direction DR1. The third cooling unit 15c is spaced apart from each of the plurality of first-phase first capacitors 1U13 in the second direction DR2. Each of the plurality of first-phase first capacitors 1U13 may be connected to the third cooling unit 15c of the cooler 1U15 via a thermal conductive spacer. The first cooling unit 15a, the second cooling unit 15b and the third cooling unit 15c constitute the cooler 1U15 as a single component, for example.

The cooler 1U15 may have any configuration as long as it can dissipate heat generated in the first-phase unit group 1U. The cooler 1U15 may be, for example, a heat sink that includes a base and a plurality of fins. The plurality of fins may be disposed on the air path of a cooling fan. The plurality of fins may extend along the first direction DR1, and may be spaced apart in the third direction DR3. The cooling fan blows air in the first direction DR1. The cooler 1U15 may have an intake wind tunnel and an exhaust wind tunnel to concentrate the airflow generated by the cooling fan around the plurality of fins. The number and arrangement of cooling fans are not particularly limited. The cooling fan may be disposed on at least one side of the intake side and the exhaust side of the cooler 1U15, and may be disposed on both sides thereof. A heat pipe may be embedded in the cooler 1U15.

As described above, each of the first-phase second power conversion circuit unit 1U2 and the first-phase third power conversion circuit unit 1U3 preferably has the same configuration as the first-phase first power conversion circuit unit 1U1.

The first-phase second power conversion circuit unit 1U2 includes a first-phase first input-side semiconductor module 1U21, a first-phase second output-side semiconductor module 1U22, and a first-phase second capacitor 1U23 illustrated in FIG. 1, and a printed circuit board and a cooler (not shown). The first-phase third power conversion circuit unit 1U3 includes a first-phase third input-side semiconductor module 1U31, a first-phase third output-side semiconductor module 1U32, and a first-phase third capacitor 1U33 illustrated in FIG. 1, and a printed circuit board and a cooler (not shown).

More preferably, the first-phase first power conversion circuit unit 1U1, the first-phase second power conversion circuit unit 1U2, and the first-phase third power conversion circuit unit 1U3 are disposed adjacent to each other in the above-described order in the third direction DR3.

As described above, each of the second-phase unit group IV and the third-phase unit group 1W preferably has the same configuration as the first-phase unit group 1U.

The second-phase unit group IV includes a second-phase first power conversion circuit unit, a second-phase second power conversion circuit unit, and a second-phase third power conversion circuit unit. Preferably, the second-phase first power conversion circuit unit, the second-phase second power conversion circuit unit, and the second-phase third power conversion circuit unit are disposed adjacent to each other in the above-described order in the third direction DR3. The third-phase unit group IW includes a third-phase first power conversion circuit unit, a third-phase second power conversion circuit unit, and a third-phase third power conversion circuit unit. Preferably, the third-phase first power conversion circuit unit, the third-phase second power conversion circuit unit, and the third-phase third power conversion circuit unit are disposed adjacent to each other in the above-described order in the third direction DR3. Preferably, the first-phase unit group 1U, the second-phase unit group 1V, and the third-phase unit group 1W are disposed adjacent to each other in the above-described order in the third direction DR3.

The first-phase first capacitor 1U13, the first-phase second capacitor 1U23, and the first-phase third capacitor 1U33 of the first-phase unit group 1U are connected in parallel to each other. The capacitors (smoothing capacitors) included in the power conversion circuit units of the first-phase unit group 1U, the second-phase unit group IV, and the third-phase unit group 1W are connected in parallel to each other. Thus, each capacitor has the same potential.

The first-phase first capacitor 1U13, the first-phase second capacitor 1U23, and the first-phase third capacitor 1U33 of the first-phase unit group 1U may be mounted on the same printed circuit board 1U14. Furthermore, the capacitors (smoothing capacitors) included in the power conversion circuit units of the first-phase unit group 1U, the second-phase unit group IV, and the third-phase unit group IW may be mounted on the same printed circuit board 1U14.

### <Example Applications of Power Conversion Device>

The power conversion device 100 according to the present embodiment may be applied to a control panel of an elevator. The control panel of an elevator is installed in a machine room disposed above a hoistway along which an elevator cage moves or in the hoistway.

In the control panel of an elevator, the power conversion device 100 converts electrical power (for example, three phase AC power) supplied from an external AC power supply PW (for example, a commercial power supply which will be simply referred to as a power supply hereinafter) via an input reactor R1 into electrical power (for example, three phase AC power) suitable for a hoisting machine M. The converted electrical power is supplied to the hoisting machine M via an output reactor R2.

In this case, the three phase AC power supplied from the power supply PW to the power conversion device 100 via the input reactor R1 is divided to the first-phase unit group 1U, the second-phase unit group IV, and the third-phase unit group 1W. The divided AC power is converted into DC power in each of the first-phase unit group 1U, the second-phase unit group 1V and the third-phase unit group 1W, and is smoothed thereafter. The smoothed DC power is converted into AC power in each of the first-phase unit group 1U, the second-phase unit group 1V and the third-phase unit group 1W, and is merged thereafter and output as three phase AC power to the hoisting machine M via the output reactor R2.

The input-side semiconductor modules of each of the first-phase unit group 1U, the second-phase unit group 1V, and the third-phase unit group 1W function as a converter that converts AC power into DC power. The output-side semiconductor modules of each of the first-phase unit group 1U, the second-phase unit group IV, and the third-phase unit group 1W function as an inverter that converts DC power into AC power. The capacitors of each of the first-phase unit group 1U, the second-phase unit group IV. and the third-phase unit group 1W function as smoothing capacitors.

Further, the power conversion device 100 converts the regenerative power generated by the hoisting machine M into electrical power suitable for charging the power source PW. The converted electrical power is supplied to the power supply PW.

In this case, the components including the output-side semiconductor modules of each of the first-phase unit group 1U, the second phase unit group IV, and the third-phase unit group 1W function as a converter circuit that converts AC power into DC power. The components including the input-side semiconductor modules of each of the first-phase unit group 1U, the second-phase unit group IV, and the third-phase unit group 1W function as an inverter circuit that converts DC power into AC power. The power conversion device 100 supplies the regenerative power generated from the hoisting machine M to the power source PW via the input reactor RI.

Note that the power conversion device 100 may be applied to applications other than a control panel for an elevator. The power conversion device 100 may be applied to, for example, a general-purpose inverter or an inverter of an air conditioner.

### <Effects of Power Conversion Device>

In the power conversion device 100, the printed circuit board 1U14 on which the first-phase first capacitor 1U13 is mounted is supported by the first-phase first input-side semiconductor module 1U11 and the first-phase first output-side semiconductor module 1U12 which are disposed to sandwich the first-phase first capacitor 1U13 in the first direction DR1, a connection failure is unlikely to occur between the first-phase first capacitor 1U13 and each of the first-phase first input-side semiconductor module 1U11 and the first-phase first output-side semiconductor module 1U12. In the power conversion device 100, a connection failure is less likely to occur between the first-phase first capacitor 1U13 and the other electronic components than in a power conversion device in which the substrate on which a capacitor is mounted is supported via a connector in a cantilever state. In particular, even when the printed circuit board 1U14 is subjected to vibrations during the usage, transportation or the like of the power conversion device 100, a connection failure is less likely to occur in the power conversion device 100 between the first-phase first capacitor 1U13 and each of the first-phase first input-side semiconductor module 1U11 and the first-phase first output-side semiconductor module 1U12.

Further, in the power conversion device 100, the printed circuit board 1U14 on which the first-phase first capacitor (the smoothing capacitor) 1U13 is mounted is detachably supported by the first-phase first input-side semiconductor module 1U11 and the first-phase first output-side semiconductor module 1U12. Therefore, in the power conversion device 100, the smoothing capacitor can be easily replaced as compared with a power conversion device in which the smoothing capacitor is mounted on the same substrate with the semiconductor element.

For example, when the smoothing capacitor is an electrolytic capacitor, the lifetime thereof is about 10 to 15 years. When the power conversion device 100 is used for a longer period than the lifetime of the smoothing capacitor, it is necessary to replace the smoothing capacitor. In such a case, according to the power conversion device 100, the smoothing capacitor can be replaced only by attaching and detaching the printed circuit board 1U14.

In the power conversion device 100, the first-phase first input-side semiconductor module 1U11 and the first-phase first output-side semiconductor module 1U12 are detachably supported by the cooler 1U15. Thus, even when it is necessary to change the power capacity of the power conversion device 100, the first-phase first input-side semiconductor module 1U11, the first-phase first output-side semiconductor module 1U12 and the printed circuit board 1U14 can be easily replaced.

In addition, in the power conversion device 100, the first-phase first input-side semiconductor module 1U11 and the first-phase first output-side semiconductor module 1U12 are disposed to sandwich the first-phase first capacitor 1U13 in the first direction DR1. In other words, when viewed from the first direction DR1, at least a part of the first-phase first capacitor 1U13 is disposed to overlap with the first-phase first input-side semiconductor module 1U11 and the first-phase first output-side semiconductor module 1U12. Therefore, the length (thickness) of the power conversion device 100 in the second direction DR2 is shorter (thinner) than that in the case where the first-phase first input-side semiconductor module 1U11 and the first-phase first output-side semiconductor module 1U12 are not disposed to sandwich the first-phase first capacitor TU13 in the first direction DR1.

In the power conversion device 100, the first cooling unit 15a and the second cooling unit 15b are disposed on the side of the first-phase first capacitor 1013 with respect to the printed board 1U14 in the second direction DR2, and the first-phase first capacitor 1U13 is spaced apart from the first cooling unit 15a and the second cooling unit 15b. Therefore, the first-phase first capacitor 1U13 is less likely to be affected by vibration of the first cooling unit 15a and the second cooling unit 15b.

In particular, when the first-phase first capacitor 1U13 is not in contact with an electronic component, the first-phase first capacitor 1013 is less likely to be affected by vibration of the electronic component, and it is possible to prevent heat from being transferred from the electronic component to the first-phase first capacitor 1U13.

In the power conversion device 100, a plurality of first-phase first capacitors 1013 are mounted on the printed circuit board 1U14. The number of the first-phase first capacitors 1U13 mounted on the printed circuit board 1U14 may be appropriately determined according to the power capacity required for the power conversion device 100.

In the power conversion device 100, since a slit 14f is formed between the first terminal 2a and the second terminal 2b having different potentials, the creepage distance between the first terminal 2a and the second terminal 2b becomes longer than the shortest distance (the length of the imaginary straight line) between the first terminal 2a and the second terminal 2b. The creepage distance between the first terminal 2a and the second terminal 2b is set equal to or longer than a distance required to electrically insulate the first terminal 2a and the second terminal 2b from each other. As a result, while electrically insulating the first terminal 2a and the second terminal 2b from each other, the shortest distance between the first terminal 2a and the second terminal 2b can be made shorter than the distance required to electrically insulate the first terminal 2a and the second terminal 2b from each other, and thereby the printed circuit board 1U14 can be miniaturized.

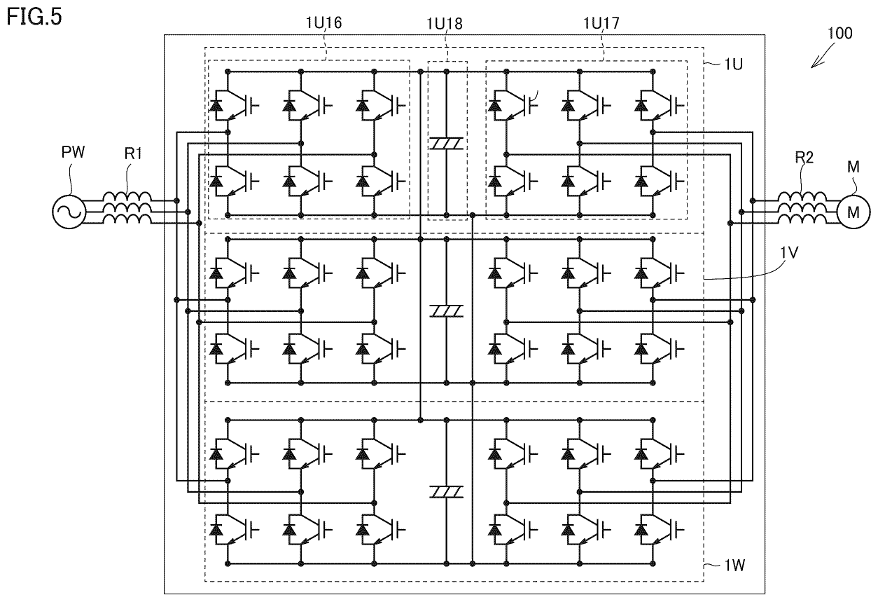

Note that the power conversion device 100 may be constituted as a power conversion device illustrated in FIG. 5 instead of the power conversion device illustrated in FIG. 1.

The power conversion device 100 illustrated in FIG. 5 includes a first-phase unit 10U. a second-phase unit 10V, and a third-phase unit 10W. Each of the first-phase unit 10U, the second-phase unit 10V, and the third-phase unit 10W constitutes a one-phase three-parallel power conversion circuit unit. The power conversion device 100 illustrated in FIG. 5 is different from the power conversion device 100 illustrated in FIG. 1 in that each of the first-phase unit 10U, the second-phase unit 10V and the third-phase unit 10W includes only one smoothing capacitor. In the power conversion device 100 illustrated in FIG. 5, the first-phase unit 10U as one power conversion circuit unit includes a first-phase input-side semiconductor module 1U16 as an input-side semiconductor module, a first-phase output-side semiconductor module 1017 as an output-side semiconductor module, and a first phase capacitor 1U18.

In this case, the relative positional relationship and the connection relationship of each of the first-phase input-side semiconductor module 1U16, the first-phase output-side semiconductor module 1U17, and the first phase capacitor 1U18 may be the same as those of each of the first-phase first input-side semiconductor module 1U11, the first-phase first output-side semiconductor module 1U12, and the first-phase first capacitor 1U13 illustrated in FIGS. 2 to 4.

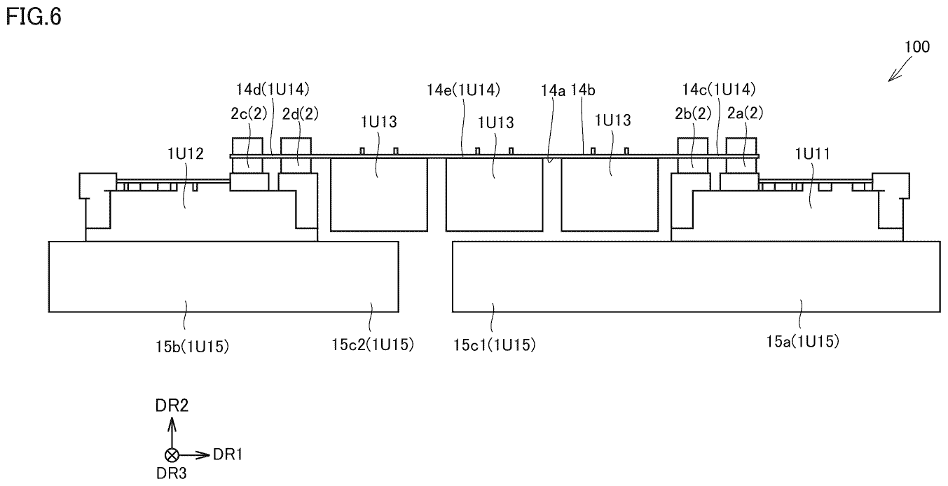

As illustrated in FIG. 6, the cooler 1U15 of the power conversion device 100 may include two cooling units of a first cooling unit 15a and a second cooling unit 15b. The first cooling unit 15a may be constituted by a first cooling unit 15a and a fourth cooling unit 15c1 spaced apart from each of the plurality of first-phase first capacitors 1U13 disposed near the first-phase first input-side semiconductor module 1U11 in the first direction DR1. The second cooling unit 15b may be constituted by a second cooling unit 15b and a fifth cooling unit 15c2 spaced apart from each of the plurality of first-phase first capacitors 1U13 disposed near the first-phase first output-side semiconductor module 1U12 in the first direction DR1. In other words, the first cooling unit 15a and the second cooling unit 15b may be separate members.

The heat capacity of each of the first cooling unit 15a and the second cooling unit 15b may be appropriately determined according to the amount of heat generated by each of the first-phase first input-side semiconductor module 1U11 and the first-phase first output-side semiconductor module 1U12. When the amount of heat generated by the first-phase first input-side semiconductor module 1U11 is larger than the amount of heat generated by the first-phase first output-side semiconductor module 1U12, it is preferable to set the heat capacity of the first cooling unit 15a larger than the heat capacity of the second cooling unit 15b as illustrated in FIG. 6.

The cooler 1U15 illustrated in FIG. 6 has improved workability (portability and mountability) as compared with the cooler 1U15 illustrated in FIG. 3. In addition, in the cooler 1U15 illustrated in FIG. 6, an inexpensive cooler may be adopted as the second cooling unit 15b which has a smaller heat capacity.

### Second Embodiment

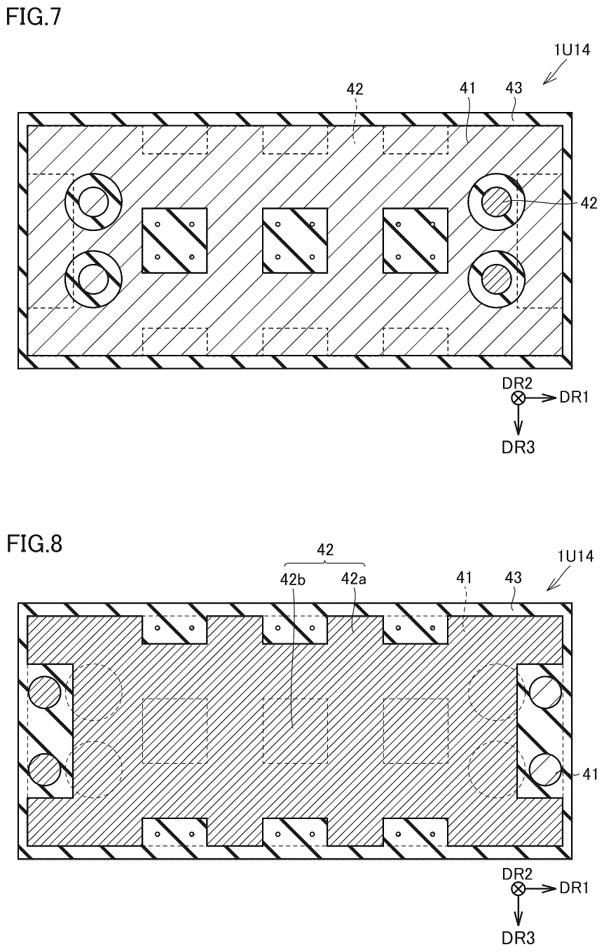

A power conversion device according to a second embodiment has basically the same configuration and exhibits the same effects as the power conversion device 100 according to the first embodiment, but is different from the power conversion device 100 according to the first embodiment in that the printed circuit board 1U14 further includes a first conductor pattern 41 and a second conductor pattern 42 having different potentials, and an area of a region of the second conductor pattern 42 that faces the first conductor pattern 41 in the second direction DR2 is 20% or more of an area of the second conductor pattern 42 as illustrated in FIGS. 7 and 8. In the following, the difference between the power conversion device according to the second embodiment and the power conversion device 100 according to the first embodiment will be mainly described. In FIG. 7, the outer edge of the second conductor pattern 42 illustrated in FIG. 8 is indicated by a dash line. In FIG. 8, the outer edge of the first conductor pattern 41 illustrated in FIG. 7 is indicated by a dash line.

The first conductor pattern 41 and the second conductor pattern 42 are spaced apart from each other in the second direction DR2. The first conductor pattern 41 and the second conductor pattern 42 are covered with an insulating film 43, and are electrically insulated from each other by the insulating film 43.

The first conductor pattern 41 is electrically connected to the first terminal 2a through a via hole or the like (not shown). Thus, the first conductor pattern 41 is electrically connected to the first-phase first input-side semiconductor module 1U11 via the first terminal 2a or the like. Further, the first conductor pattern 41 is electrically connected to one electrode of the first-phase first capacitor 1U13 through a via hole or the like (not shown).

The second conductor pattern 42 is electrically connected to the second terminal 2b through a via hole or the like (not shown). Thus, the second conductor pattern 42 is electrically connected to the first-phase first output-side semiconductor module 1U12 via the second terminal 2b or the like. Further, the second conductor pattern 42 is electrically connected to the other electrode of the first-phase first capacitor 1U13 through a via hole or the like (not shown).

As illustrated in FIG. 7, the area of a region of the first conductor pattern 41 that faces the second conductor pattern 42 in the second direction DR2 is 20% or more of the area of the first conductor pattern 41. As illustrated in FIG. 8, the area of a region of the second conductor pattern 42 that faces the first conductor pattern 41 in the second direction DR2 is 20% or more of the area of the second conductor pattern 42.

In the power conversion device according to the second embodiment, the capacitance formed by the first conductor pattern 41 and the second conductor pattern 42 is increased and the parasitic inductance component is reduced as compared with the case where the area of the region of the second conductor pattern 42 that faces the first conductor pattern 41 in the second direction DR2 is less than 20% of the area of the second conductor pattern 42. By reducing the parasitic inductance component, the surge voltage generated when the input-side semiconductor module and the output-side semiconductor module perform the switching operation is reduced.

In the power conversion device according to the second embodiment, the shape of the first conductor pattern 41 and the shape of the second conductor pattern 42 are not limited to the shapes illustrated in FIGS. 7 and 8, and may be appropriately determined.

### Third Embodiment

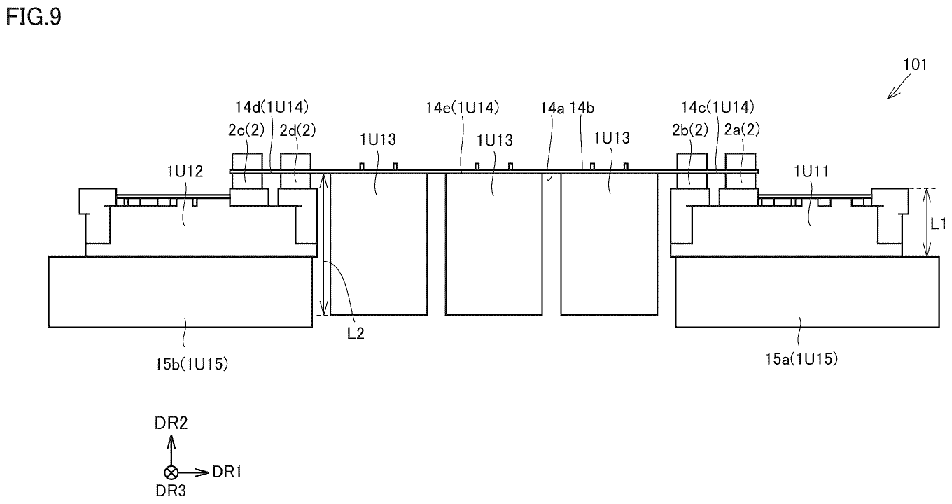

A power conversion device 101 according to a third embodiment has basically the same configuration and exhibits the same effects as the power conversion device 100 according to the first embodiment, but is different from the power conversion device 100 according to the first embodiment in that a length L2 of the first-phase first capacitor 1U13 in the second direction DR2 is longer than a length L1 of each of the first-phase first input-side semiconductor module 1U11 and the first-phase first output-side semiconductor module 1U12 in the second direction DR2, and a portion of the first-phase first capacitor 1U13 is disposed between the first cooling unit 15a and the second cooling unit 15b in the first direction DR1 as illustrated in FIG. 9. In the following, the difference between the power conversion device 101 and the power conversion device 100 will be mainly described.

In the power conversion device 101 illustrated in FIG. 9, since the area of each of the two electrodes of one first-phase first capacitor 1U13 may be set larger than that of the power conversion device 100 according to the first embodiment, the capacitance of one first-phase first capacitor 1U13 may be set larger. As a result, in the power conversion device 101, when the capacitance of the smoothing capacitor is set equal to that of the power conversion device 100, the number of the first-phase first capacitors 1U13 required to achieve the capacitance can be reduced as compared with the power conversion device 100, and thereby the area of the third portion 14e of the printed circuit board 1U14 on which the first-phase first capacitors 1U13 are mounted can be reduced.

As illustrated in FIG. 9, in the power conversion device 101, the first cooling unit 15a and the second cooling unit 15b may be separate members. In other words, the cooler 1U15 may be constituted by the first cooling unit 15a and the second cooling unit 15b separated from each other. In this way, even when the length 12 is about twice as long as the length L1, the first-phase first capacitor 1U13 may be spaced apart from the cooler 1U15 without contacting the cooler 1U15.

Further, in the power conversion device 101, the first cooling unit 15a and the second cooling unit 15b may constitute the cooler 1U15 as a single component as long as the first-phase first capacitor 1U13 may be spaced apart from the cooler 1015. The thickness of the portion of the cooler 1U15 that faces the first-phase first capacitor 1U13 in the second direction DR2 may be thinner than the thickness of each of the first cooling unit 15a and the second cooling unit 15b in the second direction DR2.

### Fourth Embodiment

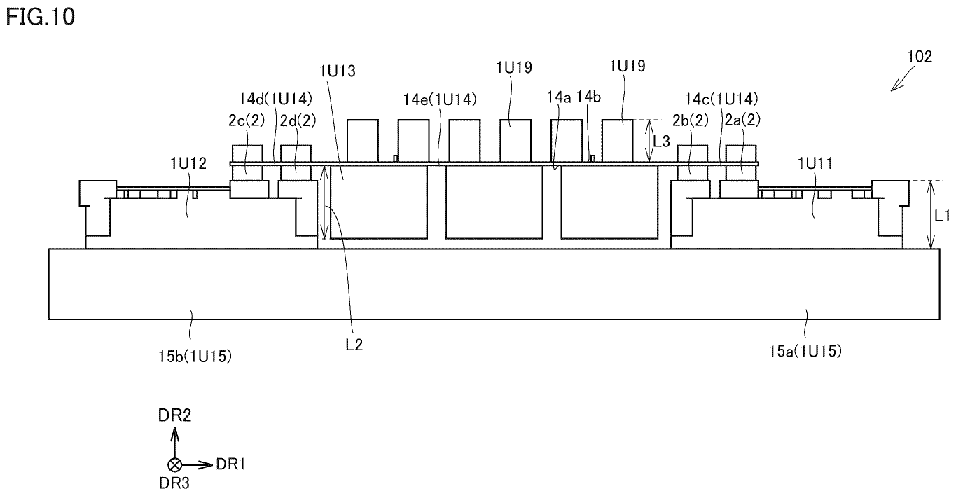

As illustrated in FIG. 10, a power conversion device 102 according to a fourth embodiment has basically the same configuration and exhibits the same effect as the power conversion device 100 according to the first embodiment, but is different from the power conversion device 100 in that it further includes at least one capacitor 1U19 mounted on the second surface 14b of the printed circuit board 1U14. In the following, the difference between the power conversion device 102 and the power conversion device 100 will be mainly described.

The power conversion device 102 includes, for example, a plurality of capacitors 1U19. The plurality of capacitors 1U19 are mounted on the third portion 14e of the printed circuit board 1U14. Each of the plurality of capacitors 1U19 is connected in parallel to the first-phase first capacitor 1U13, for example. The first-phase first output-side semiconductor module 1U12 is electrically connected to the first-phase first input-side semiconductor module 1U11 via the plurality of first-phase first capacitors 1U13 and the plurality of capacitors 1U19.

In the power conversion device 102, when the composite capacitance of the plurality of first-phase first capacitors 1U13 and the plurality of capacitors 1U19 is equal to the composite capacitance of the plurality of first-phase first capacitors 1U13 of the power conversion device 100, the number of first-phase first capacitors 1U13 required to achieve the composite capacitance can be reduced as compared with the power conversion device 100, and thereby the area of the third portion 14e of the printed circuit board 1U14 on which the plurality of first-phase first capacitors 1U13 and the plurality of capacitors 1U19 are mounted can be reduced.

Preferably, the length L3 of each of the plurality of capacitors 1U19 in the second direction DR2 is shorter than the length L2 of each of the plurality of first-phase first capacitors 1U13 in the second direction DR2. In this way, the length (thickness) in the second direction DR2 of the power conversion device 102 is shorter (thinner) than that in the case where the length of each of the plurality of capacitors 1019 in the second direction DR2 is longer than the length of each of the plurality of first-phase first capacitors 1U13 in the second direction DR2. Preferably, the length L3 of each of the plurality of capacitors 1U19 in the second direction DR2 is shorter than the length L1 of the first-phase first input-side semiconductor module 1U1l in the second direction DR2.

Each of the plurality of first-phase first capacitors 1U13 and each of the plurality of capacitors 1U19 may be a lead capacitor or a surface mount capacitor.

Preferably, each of the plurality of capacitors 1U19 is a surface mount capacitor. This increases the mounting density of the plurality of capacitors 1U19. In addition, if each of the plurality of first-phase first capacitors 1U13 and each of the plurality of capacitors 1U19 is a lead capacitor, it is highly possible that the leads of a capacitor to be mounted later on one surface may be disposed near the main body of a capacitor mounted earlier on the other surface, leading to a problem that the leads of the capacitor to be mounted later may be fixed on the other surface by soldering. On the contrary, if each of the plurality of capacitors 1U19 is a surface mount capacitor, since the plurality of capacitors 1U19 are not disposed on the first surface 14a, the problem mentioned above is unlikely to occur.

However, if the area of a region on which the plurality of first-phase first capacitors 1U13 are mounted and the area of a region on which the plurality of capacitors 1U19 are mounted are large enough to prevent the problem mentioned above from occurring, each of the plurality of first-phase first capacitors 1U13 and each of the plurality of capacitors 1U19 may be a lead capacitor.

### Fifth Embodiment

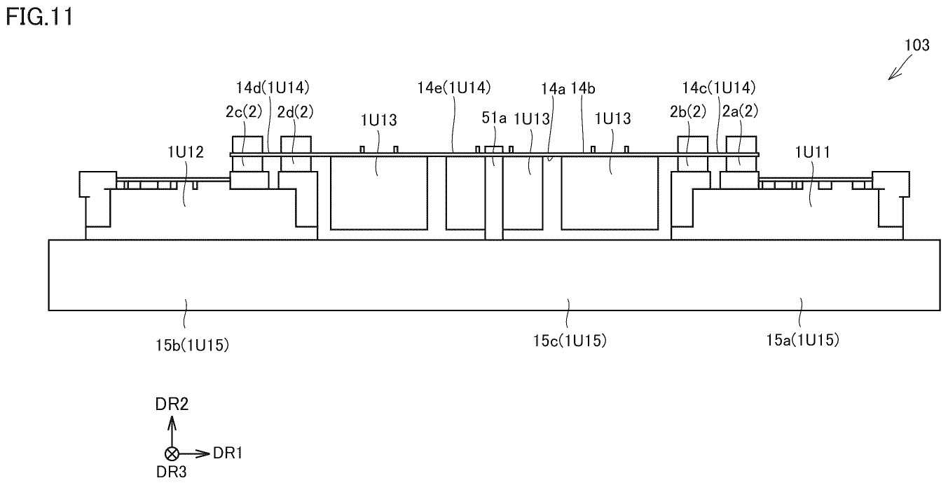

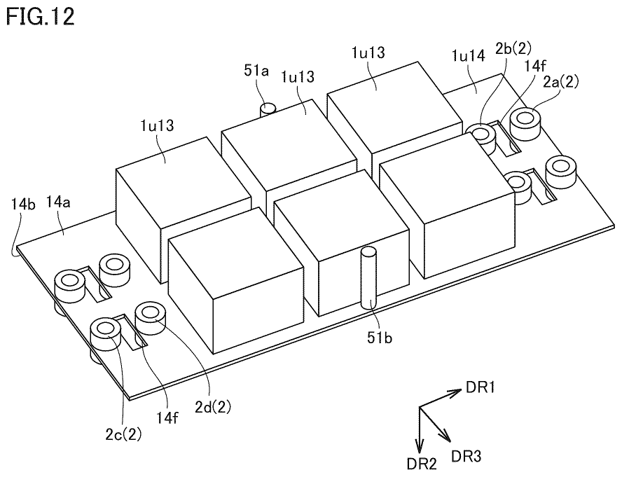

As illustrated in FIGS. 11 and 12, a power conversion device 103 according to a fifth embodiment has basically the same configuration and exhibits the same effects as the power conversion device 100 according to the first embodiment, but is different from the power conversion device 100 in that it further includes at least one support member 51a fixed to a central portion of the printed circuit board 1U14 in the long side direction (the first direction DR1). In the following, the difference between the power conversion device 103 and the power conversion device 100 will be mainly described.

The power conversion device 103 includes a plurality of support members 51a and 51b disposed between the printed circuit board 1U14 and the cooler 1015. Each of the plurality of support members 51a and 51b is not configured to electrically connect the printed circuit board 1014 and the cooler 1U15, but configured to prevent the positional variation of the printed circuit board 1U14 with respect to the cooler 1U15 in the second direction DR2. In other words, each of the plurality of support members 51a and 51b is configured to enhance the fixing strength of the printed circuit board 1U14 with respect to the cooler 1U15.

Each of the plurality of support members 51a and 51b extends along the second direction DR2. The length of each of the plurality of support members 51a, 51b in the second direction DR2 is longer than the length of each of the plurality of capacitors 1U13 in the second direction DR2. In other words, each of the plurality of support members Sla, 51b can keep each capacitor 1013 from contacting the cooler 1U15.

One end of each of the plurality of support members 51a and 51b in the second direction DR2 is fixed to, for example, a central portion of the printed circuit board 1U14 in the long side direction (the first direction DR1). In other words, one end of each of the plurality of support members 51a and 51b in the second direction DR2 is fixed to a central portion between the first terminal 2a and the third terminal 2c in the first direction DR1. One end of each of the plurality of support members 51a and 51b in the second direction DR2 is fixed to, for example, both ends of the printed circuit board 1U14 in the short side direction (the third direction DR3). In other words, the plurality of support members 51a and 51b are disposed to sandwich the plurality of capacitors 1013 in both the first direction DR1 and the third direction DR3.

The other end of each of the plurality of support members 51a and 51b in the second direction DR2 is fixed to, for example, the cooler 1U15. Specifically, the other end of each of the plurality of support members 51a and 51b in the second direction DR2 is fixed to, for example, a portion of the cooler 1U15, i.e., the third cooling unit 15c that is spaced apart from each of the plurality of first-phase first capacitors 1U13 in the second direction DR2.

The other end of each of the plurality of support members 51a and 51b in the second direction DR2 may not be fixed to the cooler 1U15 as long as the other end is in contact with the cooler 1U15. The other end of each of the plurality of support members 51a and 51b in the second direction DR2 may be in contact with the third cooling unit 15c.

In the power conversion device 103, the number of support members may be one or more. In the power conversion device 103, the one support member may be disposed at the central portion in the first direction DR1 only on one side of the capacitor 1U13 in the third direction DR3.

In the power conversion device 103, since the printed circuit board 1U14 is fixed to the cooler 1U15 by at least one support member 51a, the natural vibration frequency of the printed circuit board 1U14 when vibration is applied to the power conversion device 103 is shifted to a higher frequency than that before the support member 51a is disposed. As a result, in the power conversion device 103, since the deformation amount of the printed circuit board 1U14 is reduced as compared with the power conversion device 100 that is not provided with at least one support member 51a, the printed circuit board 1U14 is less likely to be damaged, and thereby it is expected to prolong the lifetime of the printed circuit board TU14, Further, as illustrated in FIG. 11, in the power conversion device 103 that is provided with a plurality of support members 51a and 51b, it is possible to further prevent the deformation of the printed circuit board 1U14 as compared with the power conversion device 103 that is provided with only one support member 51a.

Note that the power conversion device 103 may include three or more support members spaced apart from each other in at least one of the first direction DR1 and the third direction DR3.

As illustrated in FIG. 12, the support member 51a is, for example, a cylinder, but is not limited thereto. The support member 51a may be, for example, a polygonal prism such as a quadrangular prism or a hexagonal prism. The support member 51a may be a terminal block mounted on the printed circuit board 1014.

The method of fixing one end of the support member 51a in the second direction DR2 to the printed circuit board 1U14 is arbitrary, and may be, for example, fastening by screws or the like, caulking, or soldering. If the other end of the support member 51a in the second direction DR2 is fixed to the cooler 1U15, the method of fixing the other end is arbitrary, and may be, for example, fastening by screws or the like, caulking, or soldering.

The support member 51a may be formed as a single member or may be formed as an assembly of a plurality of members. The material constituting the support member 51a may be any material as long as it can prevent the positional variation of the printed circuit board 1U14 with respect to the cooler 1U15 in the second direction DR2, and may include, for example, at least one selected from a group consisting of a metal material such as stainless steel, brass or aluminum, and a resin material such as nylon or polyphenylene sulfide (PPS).

The power conversion device 103 may have the same configuration as the power conversion device according to the second or fourth embodiment except that the power conversion device 103 further includes at least one support member 51a fixed to the central portion of the printed circuit board 1U14 in the long side direction (the first direction DR1). For example, in the power conversion device 103, at least one support member 51a may be in contact with the fourth cooling unit 15e1 or the fifth cooling unit 15c2 illustrated in FIG. 6.

### [Aspect 1]

A power conversion device includes:
a printed circuit board having a first surface;
at least one capacitor mounted on the first surface of the printed circuit board; and
an input-side semiconductor module and an output-side semiconductor module disposed to sandwich the at least one capacitor in a first direction along the first surface and electrically connected to each other via the at least one capacitor,
the printed circuit board is detachably supported by each of the input-side semiconductor module and the output-side semiconductor module.

### [Aspect 2]

The power conversion device according to [Aspect 1] further includes:
a first cooling unit connected to the input-side semiconductor module; and
a second cooling unit connected to the output-side semiconductor module,
wherein the first cooling unit and the second cooling unit are disposed on the side of the at least one capacitor with respect to the printed circuit board in a second direction orthogonal to the first surface, and
the at least one capacitor is spaced apart from the first cooling unit and the second cooling unit.

### [Aspect 3]

In the power conversion device according to [Aspect 2], wherein
the first cooling unit and the second cooling unit constitute a cooler as a single component, and
the cooler includes a portion spaced apart from the at least one capacitor in the second direction.

### [Aspect 4]

In the power conversion device according to [Aspect 2], wherein
the first cooling unit and the second cooling unit are separate members.

### [Aspect 5]

In the power conversion device according to [Aspect 2], wherein
a length of the at least one capacitor in the second direction is longer than a length of each of the input-side semiconductor module and the output-side semiconductor module in the second direction, and
a portion of the at least one capacitor is disposed between the first cooling unit and the second cooling unit in the first direction.

### [Aspect 6]

In the power conversion device according to [Aspect 5], wherein the first cooling unit and the second cooling unit are separate members.

### [Aspect 7]

In the power conversion device according to any one of [Aspect 1] to [Aspect 6], wherein
the printed circuit board further includes a first terminal and a second terminal electrically connected to the input-side semiconductor module and having different potentials, and
the printed circuit board is formed with a slit between the first terminal and the second terminal.

### [Aspect 8]

In the power conversion device according to any one of [Aspect 1] to [Aspect 7], wherein
the printed circuit board further includes a first conductor pattern and a second conductor pattern spaced apart from each other in a second direction orthogonal to the first surface and having different potentials, and
an area of a region of the second conductor pattern that faces the first conductor pattern in the second direction is 20% or more of an area of the second conductor pattern.

### [Aspect 9]

In the power conversion device according to any one of [Aspect 1] to [Aspect 8], wherein
the at least one capacitor includes a plurality of capacitors, and
each of the plurality of capacitors includes a portion overlapping with each of the input-side semiconductor module and the output-side semiconductor module when viewed from the first direction.

### [Aspect 10]

In the power conversion device according to any one of [Aspect 1] to [Aspect 9], wherein
the printed circuit board further includes a second surface opposite to the first surface, and
the power conversion device further includes at least one capacitor mounted on the second surface of the printed circuit board.

### [Aspect 11]

In the power conversion device according to any one of [Aspect 1] to [Aspect 10], wherein
the printed circuit board includes at least one support member located on the first surface, and
the support member is in contact with the cooler.

Although the embodiments of the present disclosure have been described above, the above-described embodiments may be variously modified. Further, the scope of the present disclosure is not limited to the above-described embodiments. The scope of the present disclosure is defined by the claims and is intended to include all modifications within the meaning and range equivalent to the claims.

### REFERENCE SIGNS LIST

1U: first-phase unit group; 1U1: first-phase first power conversion circuit unit; 1U2: first-phase second power conversion circuit unit; 1U3: first-phase third power conversion circuit unit; 1U11: first-phase first input-side semiconductor module; 1U12: first-phase first output-side semiconductor module; 1U13: first-phase first-phase first capacitor; 1U14: printed circuit board; 1U15: cooler; 1U21: first-phase second input-side semiconductor module; 1U22: first-phase second output-side semiconductor module; 1U23: first-phase second capacitor; 1U31: first-phase third input-side semiconductor module; 1U32: first-phase third output-side semiconductor module; 1U33: first-phase third capacitor; 1U16: first-phase input-side semiconductor module; 1U17: first-phase output-side semiconductor module; 1U18, 1U19: capacitor; 1V: second-phase unit group; 1W: third-phase unit group; 2a: first terminal; 2b: second terminal; 2c: third terminal; 2d: fourth terminal; 10U: first-phase unit; 10V: second-phase unit; 10 W: third-phase unit; 14a: first surface; 14b: second surface; 14c: first portion; 14d: second portion; 14e: third portion; 14f: slit; 15a: first cooling unit; 15b: second cooling unit; 15c: third cooling unit; 15c1: fourth cooling unit; 15c2: fifth cooling unit; 41: first conductor pattern; 42: second conductor pattern; 43: insulating film; 51a, 51b: support member; 100, 101, 102: power conversion device.

1. A power conversion device comprising:
a printed circuit board having a first surface;
at least one capacitor mounted on the first surface of the printed circuit board; and
an input-side semiconductor module and an output-side semiconductor module disposed to sandwich the at least one capacitor in a first direction along the first surface and electrically connected to each other via the at least one capacitor,
the printed circuit board being detachably supported by each of the input-side semiconductor module and the output-side semiconductor module.

2. The power conversion device according to claim 1, further comprising:
a first cooling unit connected to the input-side semiconductor module; and
a second cooling unit connected to the output-side semiconductor module,
wherein the first cooling unit and the second cooling unit are disposed on the side of the at least one capacitor with respect to the printed circuit board in a second direction orthogonal to the first surface, and
the at least one capacitor is spaced apart from the first cooling unit and the second cooling unit.

3. The power conversion device according to claim 2, wherein
the first cooling unit and the second cooling unit constitute a cooler as a single component, and
the cooler includes a portion spaced apart from the at least one capacitor in the second direction.

4. The power conversion device according to claim 3, wherein
the printed circuit board includes at least one support member located on the first surface, and
the support member is in contact with the portion of the cooler spaced apart from the at least one capacitor in the second direction.

5. The power conversion device according to claim 2, wherein
the first cooling unit and the second cooling unit are separate members.

6. The power conversion device according to claim 2, wherein
a length of the at least one capacitor in the second direction is longer than a length of each of the input-side semiconductor module and the output-side semiconductor module in the second direction, and
a portion of the at least one capacitor is disposed between the first cooling unit and the second cooling unit in the first direction.

7. The power conversion device according to claim 6, wherein
the first cooling unit and the second cooling unit are separate members.

8. The power conversion device according to claim 1, wherein
the printed circuit board further includes a first terminal and a second terminal electrically connected to the input-side semiconductor module and having different potentials, and
the printed circuit board is formed with a slit between the first terminal and the second terminal.

9. The power conversion device according to claim 1, wherein
the printed circuit board further includes a first conductor pattern and a second conductor pattern spaced apart from each other in a second direction orthogonal to the first surface and having different potentials, and
an area of a region of the second conductor pattern that faces the first conductor pattern in the second direction is 20% or more of an area of the second conductor pattern.

10. The power conversion device according to claim 1, wherein
the at least one capacitor includes a plurality of capacitors, and
each of the plurality of capacitors includes a portion overlapping with each of the input-side semiconductor module and the output-side semiconductor module when viewed from the first direction.

11. The power conversion device according to claim 1, wherein
the printed circuit board further includes a second surface opposite to the first surface, and
the power conversion device further includes at least one capacitor mounted on the second surface of the printed circuit board.

12. The power conversion device according to claim 2, wherein
the printed circuit board further includes a first terminal and a second terminal electrically connected to the input-side semiconductor module and having different potentials, and
the printed circuit board is formed with a slit between the first terminal and the second terminal.

13. The power conversion device according to claim 2, wherein
the printed circuit board further includes a first conductor pattern and a second conductor pattern spaced apart from each other in a second direction orthogonal to the first surface and having different potentials, and
an area of a region of the second conductor pattern that faces the first conductor pattern in the second direction is 20% or more of an area of the second conductor pattern.

14. The power conversion device according to claim 2, wherein
the at least one capacitor includes a plurality of capacitors, and
each of the plurality of capacitors includes a portion overlapping with each of the input-side semiconductor module and the output-side semiconductor module when viewed from the first direction.

15. The power conversion device according to claim 2, wherein
the printed circuit board further includes a second surface opposite to the first surface, and
the power conversion device further includes at least one capacitor mounted on the second surface of the printed circuit board.

16. The power conversion device according to claim 3, wherein
the printed circuit board further includes a first terminal and a second terminal electrically connected to the input-side semiconductor module and having different potentials, and
the printed circuit board is formed with a slit between the first terminal and the second terminal.

17. The power conversion device according to claim 3, wherein
the printed circuit board further includes a first conductor pattern and a second conductor pattern spaced apart from each other in a second direction orthogonal to the first surface and having different potentials, and
an area of a region of the second conductor pattern that faces the first conductor pattern in the second direction is 20% or more of an area of the second conductor pattern.

18. The power conversion device according to claim 3, wherein
the at least one capacitor includes a plurality of capacitors, and
each of the plurality of capacitors includes a portion overlapping with each of the input-side semiconductor module and the output-side semiconductor module when viewed from the first direction.

19. The power conversion device according to claim 3, wherein
the printed circuit board further includes a second surface opposite to the first surface, and
the power conversion device further includes at least one capacitor mounted on the second surface of the printed circuit board.

20. The power conversion device according to claim 4, wherein
the printed circuit board further includes a first terminal and a second terminal electrically connected to the input-side semiconductor module and having different potentials, and
the printed circuit board is formed with a slit between the first terminal and the second terminal.
